(19) United States
(12) Patent Application Publication
(10) Pub. No.: US 2026/0040872 A1
(43) Pub. Date: Feb. 5, 2026

(54) SUBSTRATE PROCESSING SYSTEM

(71) Applicant: Tokyo Electron Limited, Tokyo (JP)

(72) Inventors: Genki OSADA, Miyagi (JP); Toshiyuki MAKABE, Miyagi (JP)

(73) Assignee: Tokyo Electron Limited, Tokyo (JP)

(21) Appl. No.: 19/357,173

(22) Filed: Oct. 14, 2025

Related U.S. Application Data
(63) Continuation of application No. PCT/JP2024/005811, filed on Feb. 19, 2024.

(30) Foreign Application Priority Data
Apr. 21, 2023 (JP) 2023-070199

(51) Int. Cl. H01L 21/67; H01L 21/677; H01L 21/68; H01L 21/683; H01L 21/687

(52) U.S. Cl. CPC H01L 21/67259; H01L 21/67098; H01L 21/67742; H01L 21/67766; H01L 21/681; H01L 21/6831; H01L 21/68721

(57) ABSTRACT

A substrate processing system including a substrate processing apparatus, a transport apparatus, and a controller. The substrate processing apparatus includes a substrate processing chamber, a substrate support, and an edge ring having a first horizontal surface and a first inclined surface. The transport apparatus includes a transport chamber, a transport arm, an optical sensor, a lens structure, and an actuator that moves the lens structure in a horizontal direction between a first horizontal position and a second horizontal position. The controller determines a consumption amount of the first horizontal surface based on an output of the optical sensor when the lens structure is at the first horizontal position, and determines a consumption amount of the first inclined surface based on an output of the optical sensor when the lens structure is at the second horizontal position.

### CROSS-REFERENCE TO RELATED APPLICATIONS

The present application is a continuation of International Application No. PCT/JP2024/005811, filed on Feb. 19, 2024, which claims priority under 35 U.S.C. § 119 to Japanese Patent Application No. 2023-070199 filed on Apr. 21, 2023, the entire contents of each of which are incorporated herein by reference.

### BACKGROUND

### Field

An exemplary embodiment of the present disclosure relates to a substrate processing system.

### Description of Related Art

US2017/53819A1 discloses that a consumption amount of a consumable component is determined by using a sensor on a transport arm. In addition, JP2022-132087A discloses that whether a substrate is present above an optical sensor is detected by using an optical sensor provided in a transport arm.

### SUMMARY

In an exemplary embodiment of the present disclosure, there is provided a substrate processing system including: a substrate processing apparatus; a transport apparatus; and a controller, in which the substrate processing apparatus includes a substrate processing chamber, a substrate support disposed in the substrate processing chamber and having a substrate support surface and a ring support surface, and an edge ring disposed on the ring support surface to surround a substrate on the substrate support surface and having a first horizontal surface and a first inclined surface, the transport apparatus includes a transport chamber, a transport arm configured to transport the substrate between the transport chamber and the substrate processing chamber, an optical sensor attached to the transport arm, a lens structure disposed below the optical sensor and having a second horizontal surface and a second inclined surface, and an actuator attached to the transport arm and configured to move the lens structure in a horizontal direction between a first horizontal position and a second horizontal position, in which the first horizontal position is a position at which the second horizontal surface overlaps an optical axis of the optical sensor and the second horizontal position is a position at which the second inclined surface overlaps the optical axis of the optical sensor, and the controller is configured to determine a consumption amount of the first horizontal surface based on an output of the optical sensor when the lens structure is at the first horizontal position, and determine a consumption amount of the first inclined surface based on an output of the optical sensor when the lens structure is at the second horizontal position.

### BRIEF DESCRIPTION OF DRAWINGS

The scope of the present disclosure is best understood from the following detailed description of exemplary embodiments when read in conjunction with the accompanying drawings.

FIG. 1 is a diagram for illustrating a configuration example of a substrate processing system.

FIG. 2 is a diagram for illustrating a configuration example of a plasma processing system.

FIG. 3 is a diagram for illustrating a configuration example of a capacitively coupled plasma processing apparatus.

FIG. 4A is a perspective view illustrating an example of a transport arm AR.

FIG. 4B is an enlarged view of a portion illustrated by D in FIG. 4A.

FIG. 5A is a diagram for illustrating an example of an angle adjustment mechanism.

FIG. 5B is a diagram for illustrating an example of the angle adjustment mechanism.

FIG. 6 is a perspective view illustrating an example of a lens structure.

FIG. 7A is a diagram for illustrating a first horizontal position of the lens structure.

FIG. 7B is a diagram for illustrating a second horizontal position of the lens structure.

FIG. 8A is a diagram for illustrating an example of measurement using the transport arm AR.

FIG. 8B is a diagram for illustrating an example of measurement using the transport arm AR.

FIG. 9 is a diagram illustrating another example of the angle adjustment mechanism.

FIG. 10 is a diagram illustrating another example of the lens structure.

### DETAILED DESCRIPTION

Hereinafter, each embodiment of the present disclosure will be described.

In an exemplary embodiment, there is provided a substrate processing system including: a substrate processing apparatus; a transport apparatus; and a controller (herein controller means the same as controller circuitry), in which the substrate processing apparatus includes a substrate processing chamber, a substrate support disposed in the substrate processing chamber and having a substrate support surface and a ring support surface, and an edge ring disposed on the ring support surface to surround a substrate on the substrate support surface and having a first horizontal surface and a first inclined surface, the transport apparatus includes a transport chamber, a transport arm configured to transport the substrate between the transport chamber and the substrate processing chamber, an optical sensor attached to the transport arm, a lens structure disposed below the optical sensor and having a second horizontal surface and a second inclined surface, and an actuator attached to the transport arm and configured to move the lens structure in a horizontal direction between a first horizontal position and a second horizontal position, in which the first horizontal position is a position at which the second horizontal surface overlaps an optical axis of the optical sensor and the second horizontal position is a position at which the second inclined surface overlaps the optical axis of the optical sensor, and the controller is configured to determine a consumption amount of the first horizontal surface based on an output of the optical sensor when the lens structure is at the first horizontal position, and determine a consumption amount of the first inclined surface based on an output of the optical sensor when the lens structure is at the second horizontal position.

In one exemplary embodiment, the optical sensor is configured to measure a first distance from the optical sensor to the first horizontal surface via the second horizontal surface when the lens structure is at the first horizontal position, and the controller is configured to determine the consumption amount of the first horizontal surface based on the first distance.

In one exemplary embodiment, the optical sensor is configured to measure a second distance from the optical sensor to the first inclined surface via the second inclined surface when the lens structure is at the second horizontal position, and the controller is configured to determine the consumption amount of the first inclined surface based on the second distance.

In one exemplary embodiment, the optical sensor is configured to measure a distance from the optical sensor to the first inclined surface via the second inclined surface when the lens structure is at the second horizontal position, and the controller is configured to determine the consumption amount of the first inclined surface based on the distance.

In one exemplary embodiment, the actuator is a piezo actuator.

In one exemplary embodiment, there is provided a substrate processing system including: a substrate processing apparatus; a transport apparatus; and a controller, in which the substrate processing apparatus includes a substrate processing chamber, and a consumable component constituting a part of the substrate processing chamber or disposed in the substrate processing chamber, and having a first horizontal surface and a first inclined surface, the transport apparatus includes a transport chamber, a transport arm configured to transport a substrate between the transport chamber and the substrate processing chamber, an optical sensor attached to the transport arm, a lens structure disposed above or below the optical sensor and having a second horizontal surface and a second inclined surface, and an actuator attached to the transport arm and configured to move the lens structure in a horizontal direction between a first horizontal position and a second horizontal position, in which the first horizontal position is a position at which the second horizontal surface overlaps an optical axis of the optical sensor and the second horizontal position is a position at which the second inclined surface overlaps the optical axis of the optical sensor, and the controller is configured to determine a state of the consumable component based on an output of the optical sensor.

In one exemplary embodiment, the optical sensor is configured to measure a first distance from the optical sensor to the first horizontal surface via the second horizontal surface when the lens structure is at the first horizontal position, and the controller is configured to determine the consumption amount of the first horizontal surface based on the first distance.

In one exemplary embodiment, the optical sensor is configured to measure a second distance from the optical sensor to the first inclined surface via the second inclined surface when the lens structure is at the second horizontal position, and the controller is configured to determine the consumption amount of the first inclined surface based on the second distance.

In one exemplary embodiment, the optical sensor is configured to measure a distance from the optical sensor to the first inclined surface via the second inclined surface when the lens structure is at the second horizontal position, and the controller is configured to determine the consumption amount of the first inclined surface based on the distance.

In one exemplary embodiment, the optical sensor is configured to measure a first distance from the optical sensor to the first horizontal surface via the second horizontal surface when the lens structure is at the first horizontal position, and the controller is configured to determine a position of the consumable component with respect to a reference position based on the first distance.

In one exemplary embodiment, the optical sensor is configured to measure a second distance from the optical sensor to the first inclined surface via the second inclined surface when the lens structure is at the second horizontal position, and the controller is configured to determine the position of the consumable component with respect to the reference position based on the first distance and the second distance.

In one exemplary embodiment, the optical sensor is configured to measure a distance from the optical sensor to the first inclined surface via the second inclined surface when the lens structure is at the second horizontal position, and the controller is configured to determine a position of the consumable component with respect to a reference position based on the distance.

In one exemplary embodiment, the actuator is a piezo actuator.

In one exemplary embodiment, there is provided a substrate processing system including: a substrate processing apparatus; a transport apparatus; and a controller, in which the substrate processing apparatus includes a substrate processing chamber, and a consumable component constituting a part of the substrate processing chamber or disposed in the substrate processing chamber, and having a first inclined surface, the transport apparatus includes a transport chamber, a transport arm configured to transport a substrate between the transport chamber and the substrate processing chamber, a sensor attached to the transport arm, and a lens structure having a second inclined surface disposed above or below the sensor, and, the controller is configured to determine a state of the consumable component based on an output of the sensor.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### Configuration Example of Substrate Processing System

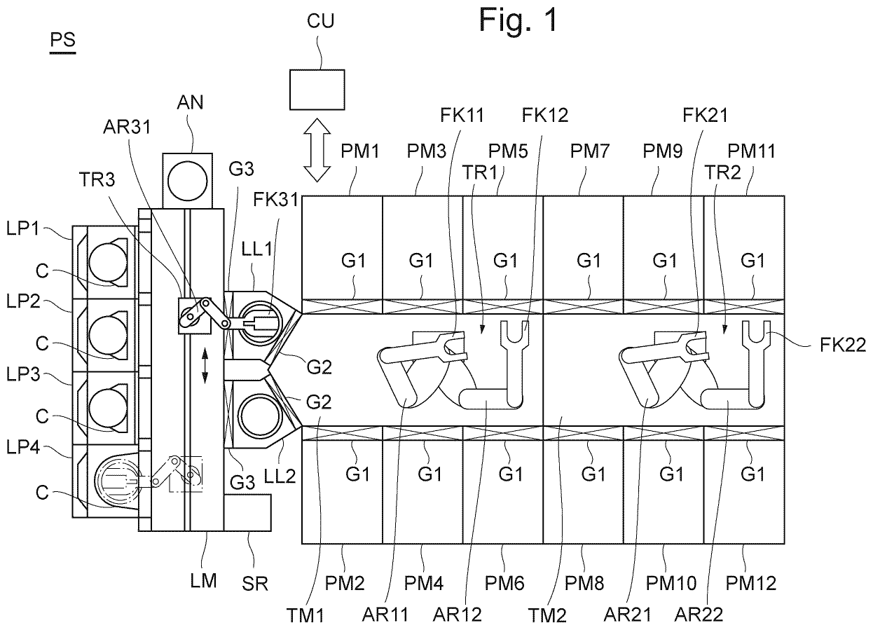

A substrate processing system (hereinafter, also referred to as a “substrate processing system PS”) according to an embodiment will be described with reference to FIG. 1. FIG. 1 is a diagram for illustrating a configuration example of the substrate processing system PS.

The substrate processing system PS includes vacuum transport modules TM1 and TM2, process modules PM1 to PM12, load lock modules LL1 and LL2, an atmospheric transport module LM, an aligner AN, a storage SR, and the like.

The vacuum transport modules TM1 and TM2 each have a substantially quadrangular shape in a plan view. In the vacuum transport module TM1, the process modules PM1 to PM6 are connected to two facing side surfaces. The load lock modules LL1 and LL2 are connected to one side surface of the other two facing side surfaces of the vacuum transport module TM1, and the path for connecting the vacuum transport module TM2 is connected to the other side surface. The side surfaces of the vacuum transport module TM1, to which the load lock modules LL1 and LL2 are connected, are angled according to the two load lock modules LL1 and LL2. In the vacuum transport module TM2, the process modules PM7 to PM12 are connected to two facing side surfaces. The path for connection to the vacuum transport module TM1 is connected to one side surface of the other two facing side surfaces of the vacuum transport module TM2. The vacuum transport modules TM1 and TM2 have a vacuum chamber in a vacuum atmosphere, and the vacuum transport robots TR1 and TR2 are disposed therein, respectively. The vacuum chambers of the vacuum transport modules TM1 and TM2 are examples of the transport chamber.

The vacuum transport robots TR1 and TR2 are configured to be capable of revolving, expanding and contracting, and lifting and lowering. The vacuum transport robots TR1 and TR2 transport a transport target object based on an operation instruction output by a controller CU described later. For example, the vacuum transport robot TR1 holds the transport target object with forks FK11 and FK12 disposed at distal ends thereof, and transports the transport target object between the load lock modules LL1 and LL2, the process modules PM1 to PM6, and the path. For example, the vacuum transport robot TR2 holds the transport target object with forks FK21 and FK22 disposed at distal ends thereof, and transports the transport target object between the process modules PM7 to PM12 and the path. The fork is also referred to as a pick or an end effector.

The transport target object includes a substrate and a consumable member. The substrate is, for example, a semiconductor wafer or a sensor wafer. The consumable member is a member attached to the process modules PM1 to PM12 in a replaceable manner, and is a member consumed by performing various types of processing such as plasma processing in the process modules PM1 to PM12. The consumable member includes, for example, members constituting a ring assembly 112 and a shower head 13, which will be described later.

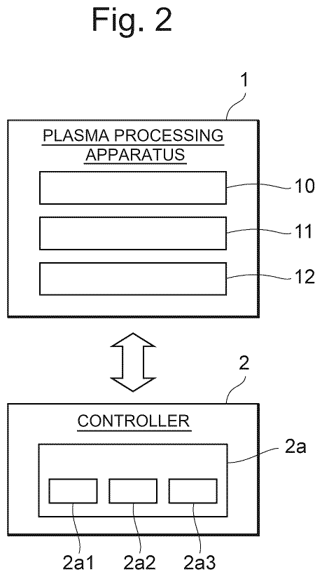

The process modules PM1 to PM12 have processing chambers and have stages (mounting tables) disposed therein. The processing chambers of the process modules PM1 to PM12 are examples of substrate processing chambers. At least one of the process modules PM1 to PM12 may be a plasma processing system (see FIG. 2) described later. For example, in at least one of the process modules PM1 to PM12, after the substrate is installed on the stage, the inside is depressurized, a processing gas is introduced, RF power is applied to form a plasma, and the substrate may be subjected to plasma processing with the plasma. The vacuum transport modules TM1 and TM2, and the process modules PM1 to PM12 are partitioned by an openable and closable gate valve G1.

The load lock modules LL1 and LL2 are disposed between the vacuum transport module TM1 and the atmospheric transport module LM. The load lock modules LL1 and LL2 have an internal pressure variable chamber of which the inside can be switched to a vacuum or atmospheric pressure. The load lock modules LL1 and LL2 have stages disposed therein. The load lock modules LL1 and LL2 maintain the inside at the atmospheric pressure to receive the substrate from the atmospheric transport module LM and reduce the pressure inside to carry in the substrate to the vacuum transport module TM1 when the substrate is transported from the atmospheric transport module LM into the vacuum transport module TM1. The load lock modules LL1 and LL2 maintain the inside in a vacuum, receive the substrate from the vacuum transport module TM1, and increase the pressure inside to the atmospheric pressure to carry in the substrate to the atmospheric transport module LM when the substrate is carried out from the vacuum transport module TM1 to the atmospheric transport module LM. The load lock modules LL1 and LL2 and the vacuum transport module TM1 are partitioned by an openable and closable gate valve G2. The load lock modules LL1 and LL2 and the atmospheric transport module LM are partitioned by an openable and closable gate valve G3.

The atmospheric transport module LM is disposed to face the vacuum transport module TM1. The atmospheric transport module LM may be, for example, an equipment front end module (EFEM). The atmospheric transport module LM is a cuboidal shape, includes a fan filter unit (FFU), and is an atmospheric transport chamber held in an atmospheric pressure atmosphere. The two load lock modules LL1 and LL2 are connected to one side surface of the atmospheric transport module LM along a longitudinal direction. The load ports LP1 to LP4 are connected to the other side surface of the atmospheric transport module LM along the longitudinal direction. A container C that accommodates a plurality of (for example, 25) substrates placed on the load ports LP1 to LP4. The container C may be, for example, a front-opening unified pod (FOUP). An atmospheric transport robot TR3 that transports the transport target object is disposed in the atmospheric transport module LM.

The atmospheric transport robot TR3 is configured to be movable along the longitudinal direction of the atmospheric transport module LM, and is configured to be capable of revolving, expanding and contracting, and lifting and lowering. The atmospheric transport robot TR3 transports the transport target object based on an operation instruction output by the controller CU which will be described later. For example, the atmospheric transport robot TR3 holds the transport target object with a fork FK31 disposed at a distal end thereof, and transports the transport target object between the load ports LP1 to LP4, the load lock modules LL1 and LL2, the aligner AN, and the storage SR.

The aligner AN is connected to one side surface of the atmospheric transport module LM along a lateral direction. However, the aligner AN may be connected to a side surface of the atmospheric transport module LM along the longitudinal direction. In addition, the aligner AN may be provided inside the atmospheric transport module LM. The aligner AN includes a support table, an optical sensor, and the like. The aligner referred to here is an apparatus that detects a position of the transport target object.

The support table is a table rotatable about an axis center extending in a vertical direction, and is configured to support the substrate thereon. The support table is rotated by a drive apparatus. The drive apparatus is controlled by the controller CU described later. When the support table is rotated by the power from the drive apparatus, the substrate installed on the support table is also rotated.

The optical sensor detects an edge of the substrate while the substrate is rotated. The optical sensor detects a deviation amount of an angle position of a notch (or another marker) of the substrate with respect to a reference angle position and a deviation amount of a center position of the substrate with respect to a reference position from a detection result of an edge. The optical sensor outputs the deviation amount of the angle position of the notch and the deviation amount of the center position of the substrate to a controller CU described later. The controller CU calculates an amount of rotation of a rotation support table for correcting the angle position of the notch to the reference angle position based on the deviation amount of the angle position of the notch. The controller CU controls the drive apparatus to rotate the rotation support table by the amount of rotation. Accordingly, the angle position of the notch can be corrected to the reference angle position. In addition, the controller CU controls the position of the fork FK31 of the atmospheric transport robot TR3 when receiving the substrate from the aligner AN based on the deviation amount of the center position of the substrate to make the center position of the substrate coincide with a predetermined position on the fork FK31 of the atmospheric transport robot TR3.

The storage SR is connected to the side surface of the atmospheric transport module LM along the longitudinal direction. However, the storage SR may be connected to the side surface of the atmospheric transport module LM along the lateral direction. In addition, the storage SR may be provided inside the atmospheric transport module LM. The storage SR accommodates the transport target object.

The substrate processing system PS is connected to the controller CU via a communication interface. In an embodiment, a part or all of the controller CU may be included in the substrate processing system PS. The controller CU may be, for example, a computer. The controller CU includes a central processing unit (CPU), a random access memory (RAM), a read only memory (ROM), an auxiliary storage apparatus, and the like. The CPU operates based on a program stored in the ROM or the auxiliary storage apparatus, and controls each unit of the substrate processing system PS. For example, the controller CU outputs the operation instruction to the vacuum transport robots TR1 and TR2, the atmospheric transport robot TR3, and the like. The operation instruction includes an instruction for registration of the forks FK11, FK12, FK21, FK22, and FK31 for transporting the transport target object with a transport location of the transport target object. The controller circuitry can be programmable circuitry (e.g., embedded processor) or fixed circuitry (e.g., ASIC or PAL). In an exemplary embodiment, the controller circuitry can include one or more programmable processors/controllers.

### Configuration Example of Plasma Processing System

An example of the plasma processing system that may be employed as at least one of the process modules PM1 to PM12 will be described with reference to FIG. 2. FIG. 2 is a diagram for illustrating a configuration example of the plasma processing system. In an embodiment, the plasma processing system includes a plasma processing apparatus 1 and a controller 2.

In an embodiment, the plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20 which is described later, and the gas exhaust port is connected to an exhaust system 40 which is described later. The substrate support 11 is disposed in the plasma processing space and has a substrate support surface for supporting the substrate.

The plasma generator 12 is configured to form the plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. Further, various types of plasma generators including an alternating current (AC) plasma generator and a direct current (DC) plasma generator may be used. In an embodiment, an AC signal (AC power) used in the AC plasma generator has a frequency in the range of 100 kHz to 10 GHz. Therefore, the AC signal includes a radio frequency (RF) signal and a microwave signal. In an embodiment, the RF signal has a frequency in the range of 100 kHz to 150 MHz.

The controller 2 processes a computer-executable instruction that causes the plasma processing apparatus 1 to execute various steps described in the present disclosure. The controller 2 may be configured to control each element of the plasma processing apparatus 1 to execute the various steps described here. In an embodiment, a part or all of the controller 2 may be included in the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance, or may be acquired via a medium when necessary. The acquired program is stored in the storage 2a2, is read out from the storage 2a2, and executed by the processor 2a1. The medium may be various storage media readable by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The controller CU in FIG. 1 may also have some or all of the functions of the controller 2.

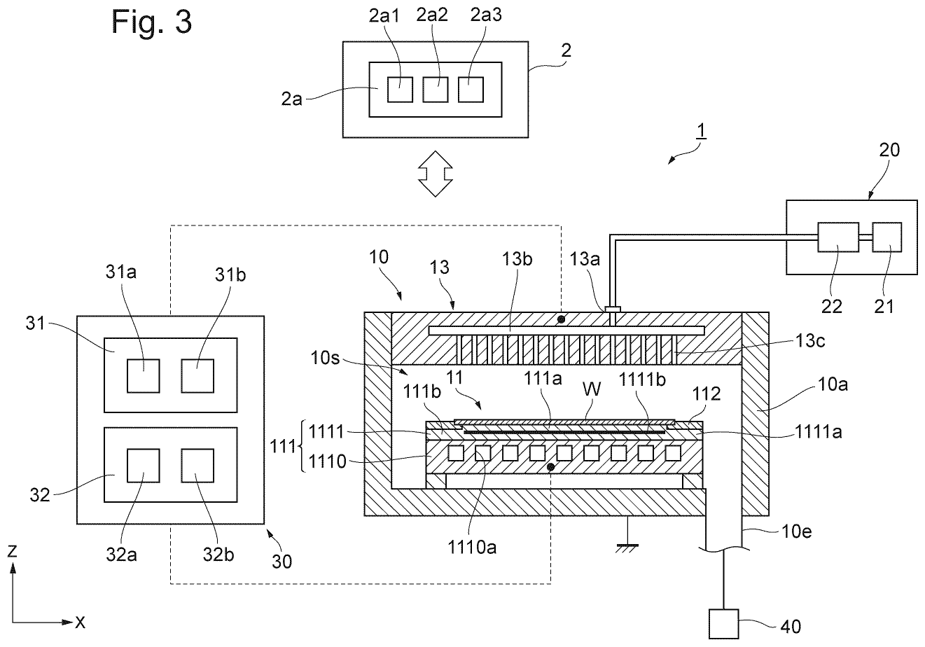

A configuration example of a capacitively coupled plasma processing apparatus as an example of the plasma processing apparatus 1 will be described with reference to FIG. 3. FIG. 3 is a diagram for illustrating the configuration example of the capacitively coupled plasma processing apparatus.

The capacitively coupled plasma processing apparatus 1 includes the plasma processing chamber 10, the gas supply 20, a power supply 30, and the exhaust system 40. In addition, the plasma processing apparatus 1 includes the substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In an embodiment, the shower head 13 configures at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a center region 111a for supporting a substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. Further, at least one RF/DC electrode coupled to an RF power supply 31 and/or a DC power supply 32, which will be described later, may be disposed in the ceramic member 1111a. In this case, at least one RF/DC electrode functions as the lower electrode. In a case where a bias RF signal and/or a DC signal, which will be described later, are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Therefore, the substrate support 11 includes at least one lower electrode.

The ring assembly 112 includes one or a plurality of annular members. In an embodiment, one or the plurality of annular members includes one or a plurality of edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or a plurality of heaters is disposed in the ceramic member 1111a of the electrostatic chuck 1111. Further, the substrate support 11 may include a heat transfer gas supply configured to supply the heat transfer gas to a gap between a back surface of the substrate W and the center region 111a.

The shower head 13 is configured to introduce at least one processing gas into the plasma processing space 10s from the gas supply 20. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode. In addition to the shower head 13, the gas introducer may include one or a plurality of side gas injectors (SGI) attached to one or a plurality of opening portions formed on the side wall 10a.

The gas supply 20 may include at least one gas source 21 and at least one flow rate controller 22. In an embodiment, the gas supply 20 is configured to supply at least one processing gas to the shower head 13 from each corresponding gas source 21 via each corresponding flow rate controller 22. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. As a result, plasma is formed from at least one processing gas supplied to the plasma processing space 10s. Therefore, the RF power supply 31 may function as at least a part of the plasma generator 12. Further, by supplying the bias RF signal to at least one lower electrode, a bias potential is generated in the substrate W, and an ion component in the formed plasma is able to be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma formation. In an embodiment, the source RF signal has a frequency in the range of 10 MHz to 150 MHz. In an embodiment, the first RF generator 31a may be configured to generate a plurality of source RF signals having different frequencies. The generated one or the plurality of source RF signals is supplied to at least one lower electrode and/or at least one upper electrode.

The second RF generator 31b is coupled to at least one lower electrode via at least one impedance matching circuit and is configured to generate the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has the frequency in the range of 100 kHz to 60 MHz. In an embodiment, the second RF generator 31b may be configured to generate a plurality of bias RF signals having different frequencies. The generated one or the plurality of bias RF signals is supplied to at least one lower electrode. In addition, in various embodiments, at least one of the source RF signal and the bias RF signal may be pulsed.

In addition, the power supply 30 may include a DC power supply 32 coupled to the plasma processing chamber 10. The DC power supply 32 includes a first DC generator 32a and a second DC generator 32b. In an embodiment, the first DC generator 32a is connected to at least one lower electrode, and is configured to generate a first DC signal. The generated first DC signal is applied to at least one lower electrode. In an embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure the voltage pulse generator. In a case where the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or a plurality of positively-polarized voltage pulses and one or a plurality of negatively-polarized voltage pulses in one cycle. The first and second DC generators 32a and 32b may be provided in addition to the RF power supply 31, and the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

### Configuration Example of Transport Arm

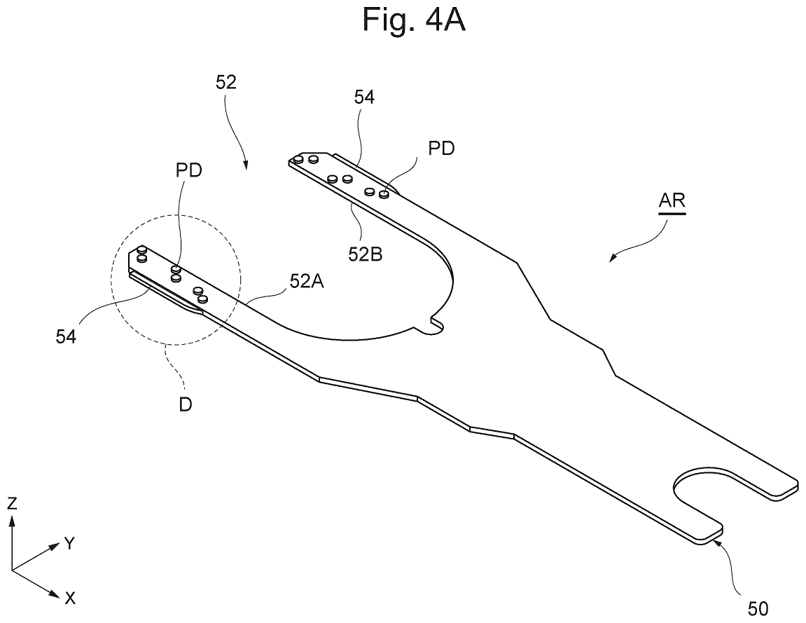

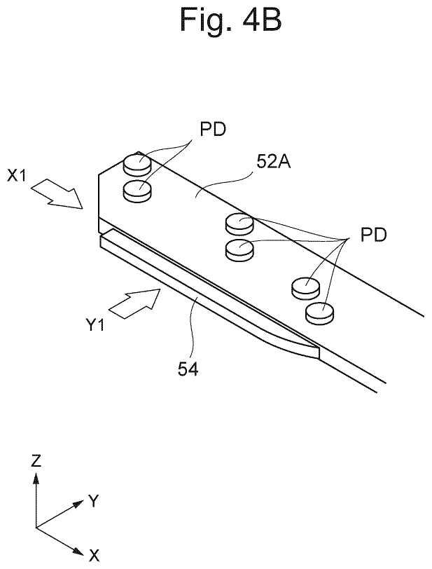

A transport arm (hereinafter, also referred to as a “transport arm AR”) according to an embodiment will be described with reference to FIGS. 4A and 4B. FIG. 4A is a perspective view illustrating an example of the transport arm AR. FIG. 4B is an enlarged view of a portion illustrated by D in FIG. 4A.

The transport arm AR is configured to transport the transport target object, such as the substrate or the consumable member, between the transport chamber and the substrate processing chamber. In an embodiment, the transport arm AR is used as the fork FK11, FK12, FK21, FK22, or FK31 of the substrate processing system illustrated in FIG. 1. In an embodiment, the transport arm AR transports the transport target object between the vacuum chambers of the vacuum transport modules TM1 and TM2 illustrated in FIG. 1 and the processing chambers (including the plasma processing chamber 10 illustrated in FIGS. 2 and 3) of the process modules PM1 to PM12.

In an embodiment, the transport arm AR has a proximal end 50 and a distal end 52 as illustrated in FIG. 4A. The transport arm AR may be connected to a drive mechanism of the transport apparatus (for example, the vacuum transport robots TR1 and TR2, the atmospheric transport robot TR3, or the like in FIG. 1) at the proximal end 50. In an embodiment, the transport arm AR can perform one or more operations of translation (horizontal movement in an XY plane), lifting and lowering (vertical movement in a Z-axis direction), and revolution (rotation about each axis of X, Y, and Z axes) by the drive mechanism.

In an embodiment, the transport target object is placed on the distal end 52 of the transport arm AR. The distal end 52 may be configured in a substantially U-shape and may include two end portions 52A and 52B spaced from each other. In an embodiment, a plurality of pads PD is provided on a surface of the distal end 52. The plurality of pads PD comes into contact with a lower surface of the transport target object (for example, the substrate) and hold the transport target object. In an embodiment, one or a plurality of suction holes may be provided at the distal end 52. The suction hole may be connected to an exhaust apparatus such as a vacuum pump. In this case, the transport target object is vacuum-suctioned to the transport arm AR via the suction hole.

The transport arm AR includes one or more optical sensors 54. In an embodiment, the optical sensors 54 are provided along side surfaces (XZ plane) of the distal end 52 (end portions 52A and 52B) as illustrated in FIGS. 4A and 4B.

In an embodiment, the optical sensor 54 is a distance sensor. For example, the optical sensor 54 may be configured to measure a distance to a measurement target object by irradiating the measurement target object with light. In an example, the optical sensor 54 is a confocal chromatic sensor. The confocal chromatic sensor measures the distance to the measurement target object based on a wavelength of the light focused and reflected on the measurement target object. In an embodiment, the optical sensor 54 is a light intensity sensor. For example, the optical sensor 54 may be configured to measure the intensity of light reflected from the measurement target object by irradiating the measurement target object with light. In an embodiment, the optical sensor 54 has both functions of the distance sensor and the light intensity sensor.

Here, in general, in order to maintain the measurement accuracy of the optical sensor, the light emitted from the optical sensor needs to be incident on the surface of the measurement target object in a given angular range (hereinafter, this range is also referred to as a “measurable range”). The measurable range varies depending on a type and a size of the optical sensor, but in a case of a small optical sensor that can be mounted on the transport arm, the measurable range tends to be narrow. Therefore, depending on a surface shape of the measurement target object or an installation location of the measurement target object, the measurement may exceed the measurable range of the optical sensor. As a result, the measurement accuracy by the optical sensor is decreased, or the measurement itself is difficult. On the other hand, adjusting a posture or position of the transport arm according to the surface shape or the installation location of the measurement target object requires complicated control or additional configuration, and it is not easy as it is necessary to avoid collision with other structures.

In this regard, as will be described below, the transport arm AR according to an embodiment further includes a mechanism (hereinafter, also referred to as an “angle adjustment mechanism”) that adjusts an angle of the light emitted from the optical sensor 54. As a result, the decrease in measurement accuracy of the optical sensor 54 is suppressed. In an embodiment, the measurable range of the optical sensor 54 may be 90°±5°, 90°±3°, 90°±1.5°, or 90°±1.0°. For example, in a case where the confocal chromatic sensor is used as the optical sensor 54, the measurable range may be, for example, 90°±1.5°.

### Configuration Example of Angle Adjustment Mechanism

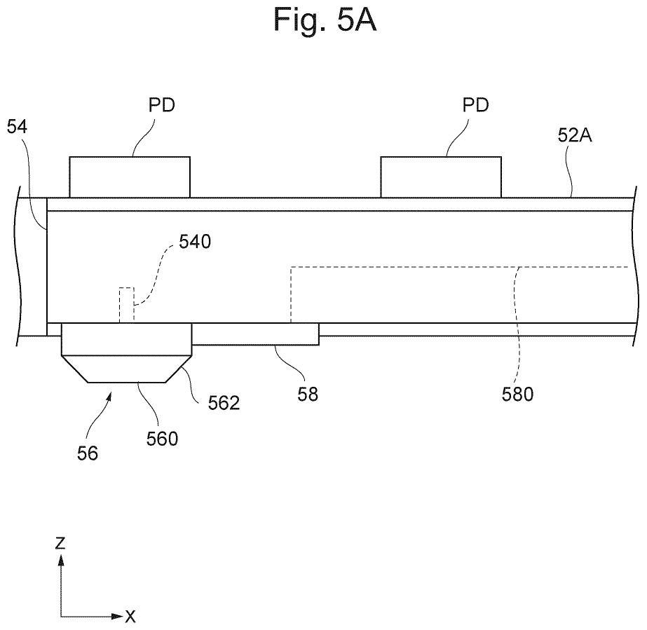

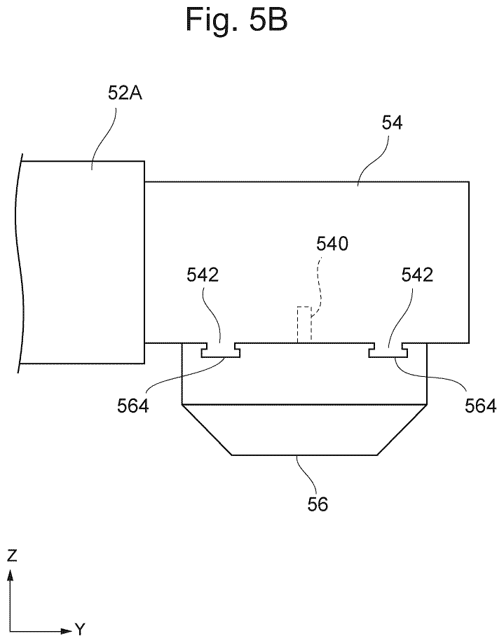

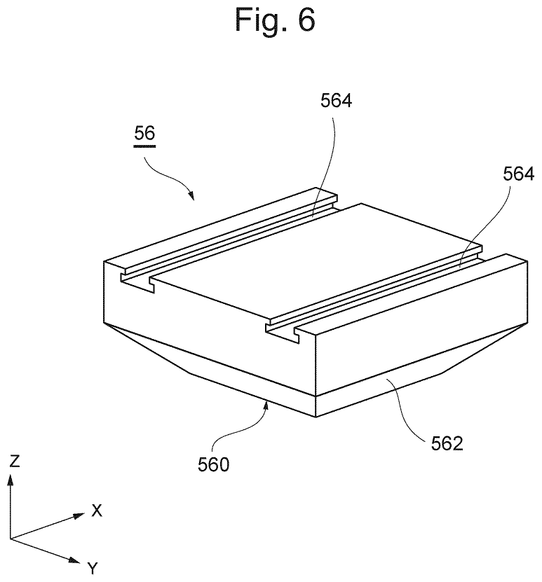

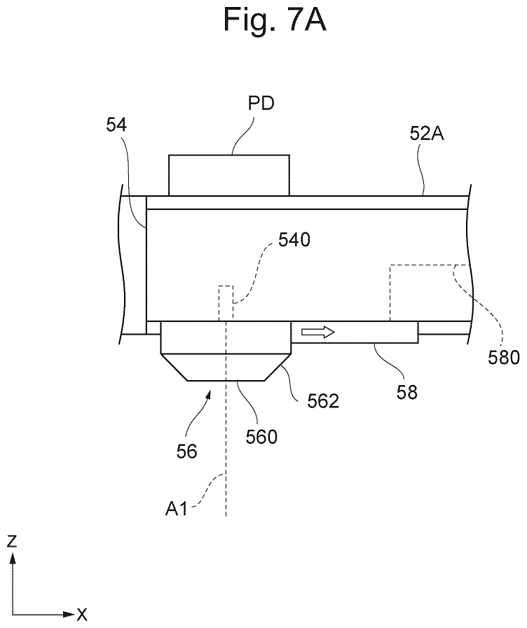

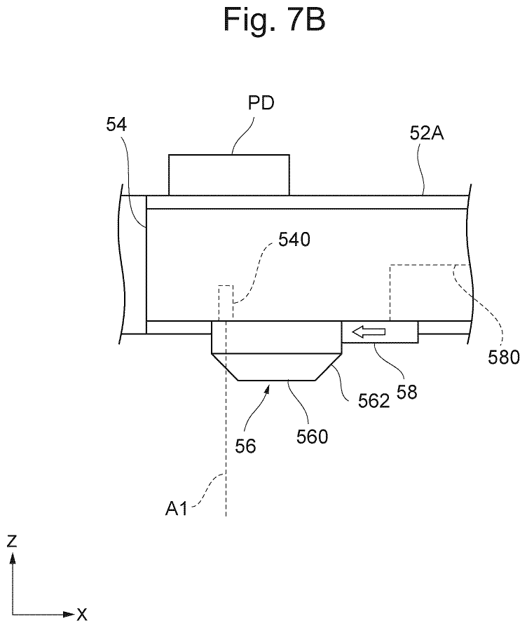

The configuration of the angle adjustment mechanism will be described with reference to FIGS. 5A to 7B. Here, FIGS. 5A and 5B are diagrams for illustrating an example of the angle adjustment mechanism. FIG. 5A is a schematic diagram of the end portion 52A of the transport arm AR of FIG. 4B as viewed from a Y1 direction. FIG. 5B is a schematic diagram of the end portion 52A of the transport arm AR of FIG. 4B as viewed from an X1 direction. FIG. 6 is a perspective view illustrating an example of a lens structure. FIG. 7A is a diagram for illustrating a first horizontal position of the lens structure. FIG. 7B is a diagram for illustrating a second horizontal position of the lens structure. In addition, the end portion 52B of the transport arm AR may also be provided with the same angle adjustment mechanism as the end portion 52A.

As illustrated in FIGS. 5A and 5B, the angle adjustment mechanism includes a lens structure 56 and an actuator 58. In an embodiment, the lens structure 56 is disposed below the optical sensor 54 in the vertical direction (z-axis direction). The lens structure 56 is disposed at a position that overlaps the optical sensor 54 in plan view. In an embodiment, as illustrated in FIGS. 5A and 5B, the optical sensor 54 may have an optical head 540 that emits light for measurement downward. In this case, the lens structure 56 may be disposed below the optical head 540.

The lens structure 56 includes a horizontal surface 560 and an inclined surface 562 that forms an angle with respect to the horizontal surface 560. The horizontal surface 560 and the inclined surface 562 are each an example of a second horizontal surface and a second inclined surface. The lens structure 56 may have various shapes in plan view, and may have a rectangular shape, a polygonal shape, a circular shape, an elliptical shape, or the like. In an example, the lens structure 56 has the rectangular shape in plan view. In an embodiment, the lens structure 56 may be made of a material having a given refractive index, such as optical glass or organic glass.

The lens structure 56 is attached to the optical sensor 54 so as to be movable in parallel to the optical sensor 54. In an embodiment, as illustrated in FIG. 5B, one or a plurality of rails 542 extending in the longitudinal direction (x-axis direction) may be provided on a lower surface of the optical sensor 54. In addition, one or a plurality of groove portions 564 extending in the longitudinal direction (x-axis direction) may be provided on an upper surface of the lens structure 56 (see FIGS. 5B and 6). Then, the groove portion 564 of the lens structure 56 may be fitted to the rail 542 on the lower surface of the optical sensor 54, and the lens structure 56 may be attached to be movable along the rail 542 in the longitudinal direction (x-axis direction).

The lens structure 56 may be attached to the optical sensor 54 in various aspects. For example, the groove portion and the rail described above may be provided in the lateral direction (y-axis direction) instead of the longitudinal direction (x-axis direction). In this case, the lens structure 56 is configured to be movable in the lateral direction (y-axis direction) along the rail 542. In addition, for example, the groove portion and the rail described above may be provided in a cross shape along the longitudinal direction and the lateral direction. In this case, the lens structure 56 is configured to be movable in the longitudinal direction and the lateral direction along the cross-shaped rail of the optical sensor 54. In addition, for example, the groove portion may be provided in the optical sensor 54, and the rail may be provided in the lens structure 56. In addition, for example, the lens structure 56 may be attached to the optical sensor 54 via another member that can be moved in parallel to the optical sensor 54.

In an embodiment, the actuator 58 is disposed below the optical sensor 54. The actuator 58 converts electric energy supplied via a wiring 580 into mechanical motion to provide a drive force required for the movement of the lens structure 56. The actuator 58 is disposed to make a drive direction thereof coincide with a movement direction (for example, the x-axis direction) of the lens structure 56. In a case where the lens structure 56 is moved in a plurality of directions (for example, the x-axis direction and the y-axis direction), a plurality of actuators 58 may be provided.

In an embodiment, the actuator 58 may be a piezo actuator. In this case, the actuator 58 is attached to the lens structure 56 to make an expansion and contraction direction of the piezo element coincide with the movement direction (for example, the x-axis direction) of the lens structure 56.

The lens structure 56 is movable below the optical sensor 54 at least between the first horizontal position and the second horizontal position by driving (for example, expansion and contraction of the piezo actuator) of the actuator 58. As illustrated in FIG. 7A, the first horizontal position is a position where the horizontal surface 560 of the lens structure 56 overlaps an optical axis A1 of the optical sensor 54 (in FIG. 7A, the optical axis A1 is a direction in which light emitted immediately after being emitted from the optical head 540 of the optical sensor 54 travels). As illustrated in FIG. 7B, the second horizontal position is a position where the inclined surface 562 of the lens structure 56 overlaps the optical axis A1 of the optical sensor 54.

### Example of Measurement Using Transport Arm

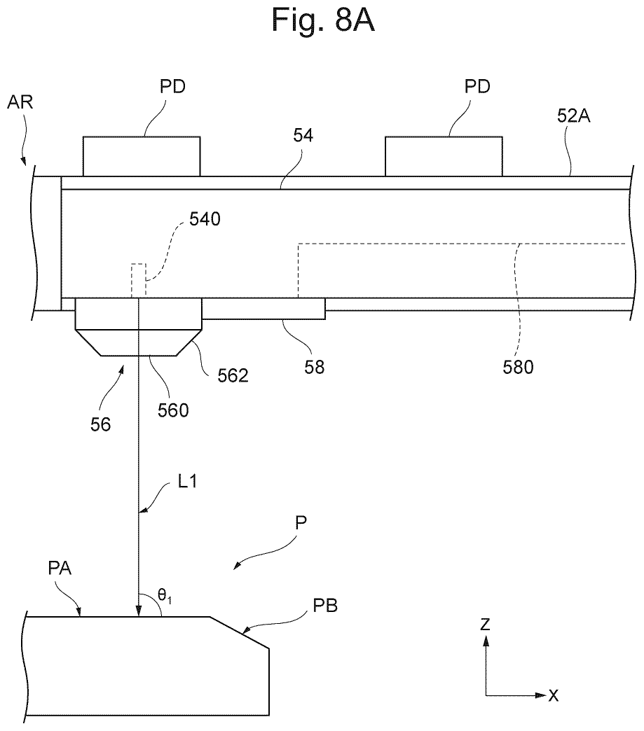

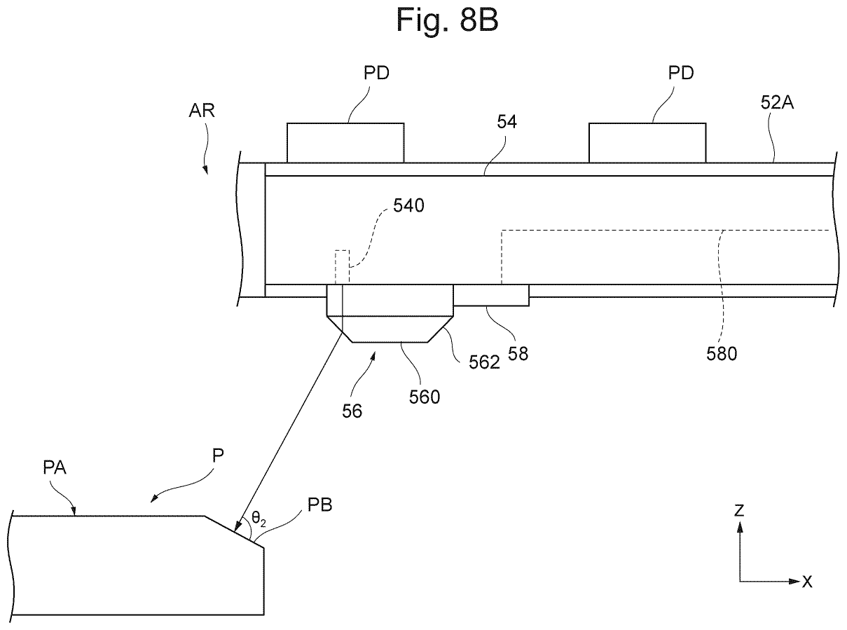

An example of measurement using the transport arm AR will be described with reference to FIGS. 8A and 8B. FIGS. 8A and 8B are diagrams for illustrating an example of the measurement using the transport arm AR. Here, a case where a component P of the plasma processing apparatus 1 illustrated in FIG. 3 is measured using the optical sensor 54 of the transport arm AR will be described as an example. In an embodiment, the component P may be a consumable component such as the ring assembly 112. In an embodiment, the measurement of the component P may be the measurement of a distance from the optical sensor 54 to the component P.

In an embodiment, the transport arm AR is introduced into the plasma processing chamber 10 (hereinafter, also referred to as the “chamber 10”) of the plasma processing apparatus 1. Then, the transport arm AR is moved in the chamber 10 in the horizontal direction (direction parallel to the XY plane).

FIG. 8A is an example of a case where a horizontal surface PA of the component P is measured. The horizontal surface PA is an example of a first horizontal surface. When measuring the horizontal surface PA, as illustrated in FIG. 8A, the lens structure 56 is disposed at the first horizontal position by the actuator 58. A light L1 emitted from the optical head 540 of the optical sensor 54 passes through the horizontal surface 560 of the lens structure 56 and travels straight. Accordingly, the light L1 is incident on the horizontal surface PA of the component P at an angle θ1. The angle θ1 is about 90°, and is, in an example, 90°+5°, 90°±3°, 90°±1.5°, or 90°±1.0°. In an embodiment, the optical sensor 54 detects a distance (hereinafter, also referred to as a “first distance”) from the optical sensor 54 to the horizontal surface PA using the light L1, and outputs the distance to the controller 2.

FIG. 8B is an example of a case where an inclined surface PB of the component P is measured. The inclined surface PB is a surface having an angle with respect to the horizontal surface PA. The inclined surface PB is an example of a first inclined surface. When measuring the inclined surface PB, as illustrated in FIG. 8B, the lens structure 56 is disposed at the second horizontal position by the actuator 58. A light L2 emitted from the optical head 540 of the optical sensor 54 passes through the inclined surface 562 of the lens structure 56 to be refracted. Accordingly, the light L2 is incident on the inclined surface PB of the ring assembly at an angle θ2. The angle θ2 is about 90°, and is, in an example, 90°±5°, 90°±3°, 90°±1.5°, or 90°±1.0°. In an embodiment, the optical sensor 54 detects a distance (hereinafter, also referred to as a “second distance”) from the optical sensor 54 to the inclined surface PB using the light L2, and outputs the distance to the controller 2.

In an embodiment, the controller 2 may determine a state of the component P based on the output from the optical sensor 54. The state of the component P may be a consumption amount of the component P or may be a position (positional deviation) of the component P with respect to the reference position.

In an embodiment, the controller 2 may determine the consumption amount of the component P based on the output from the optical sensor 54. For example, the consumption amount of the component P may be determined by measuring and storing the first distance at a time point when the component P is first installed in the chamber 10, and comparing the first distance with the first distance measured again after a given time has elapsed. In addition, for example, instead of or in addition to the comparison of the first distance, the consumption amount of the component P may be determined by measuring and storing the second distance at a time point when the component P is installed in the chamber 10, and comparing the second distance with the second distance measured again after a given time has elapsed.

In an embodiment, the controller 2 may determine the position of the component P with respect to the reference position (including the positional deviation from the reference position) based on the output from the optical sensor 54. For example, in a case where the component P is installed in the chamber 10, or the like, the first distance and/or the second distance may be measured, and the position of the component P with respect to the reference position or the positional deviation may be determined based on the measurement result.

In an embodiment, since the transport arm AR includes the angle adjustment mechanism, the light emitted from the optical sensor 54 is also incident on the inclined surface PB at an angle (for example, about 90°) within the measurable range, as in the horizontal surface PA. Accordingly, it is possible to suppress a decrease in measurement accuracy of the optical sensor 54 on the inclined surface PB. In an embodiment, the transport arm AR includes the angle adjustment mechanism, so that the light emitted from the optical sensor 54 can be refracted. Accordingly, the component P at a position farther from the transport arm AR can be irradiated with light. That is, the measurement region by the optical sensor 54 can be widened.

### Modification Example

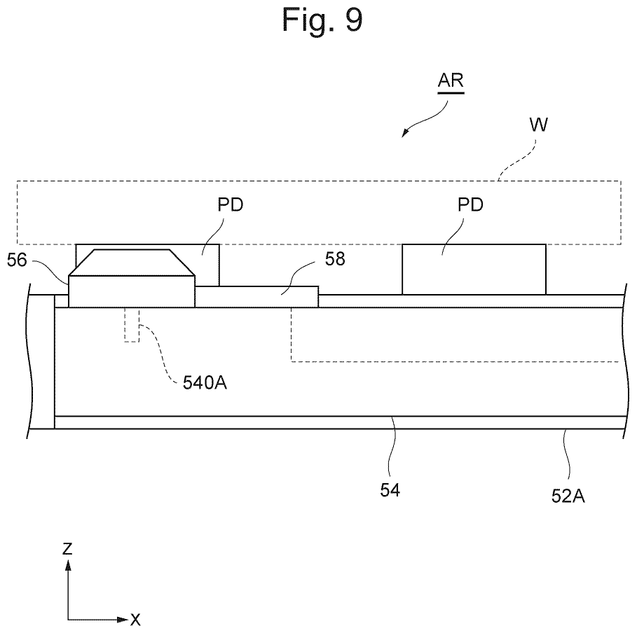

FIG. 9 is a diagram illustrating another example of the angle adjustment mechanism. In an embodiment, the angle adjustment mechanism may be disposed above the optical sensor. In the example illustrated in FIG. 9, the optical sensor 54 includes an exposure head 540A that emits light upward in the vertical direction (z-axis direction). The lens structure 56 is disposed above the exposure head 540A. The actuator 58 is disposed above the optical sensor 54. Accordingly, the optical sensor 54 can measure the component P above the transport arm AR. Examples of the component P include the shower head 13 of the plasma processing apparatus 1.

In the example illustrated in FIG. 9, the upper surface (position in the z-axis direction) of the lens structure 56 is at a position lower than an upper surface of the pad PD. Accordingly, in a case where the transport target object (for example, the substrate W) is placed on the pad PD, the lens structure 56 is suppressed from coming into contact with the transport target object.

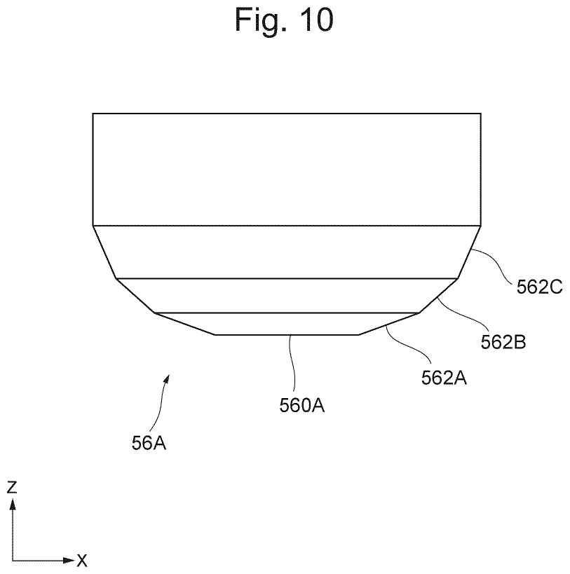

FIG. 10 is a diagram illustrating another example of the lens structure. In an embodiment, the lens structure may include an inclined surface of a plurality of angles. In the example illustrated in FIG. 10, the lens structure 56A includes a horizontal surface 560A and three inclined surfaces 562A to 562C having different angles with respect to the horizontal surface 560A, respectively. The lens structure 56A may be disposed to be movable below (above) the optical sensor 54 (54A) as in the examples illustrated in FIGS. 5A and 9. In this case, the lens structure 56A may be configured to be movable at least between the first horizontal position, the second horizontal position, a third horizontal position, and a fourth horizontal position below (above) the optical sensor 54 (54A). The first horizontal position is a position at which the horizontal surface 560A of the lens structure 56A overlaps the optical axis of the optical sensor 54 (54A). The second to fourth horizontal positions are positions at which the inclined surfaces 562A to 562C of the lens structure 56A overlap the optical axis of the optical sensor 54 (54A), respectively. According to this configuration, the angle of the light emitted from the optical sensor 54 (54A) can be more finely adjusted, and thus the measurement accuracy can be further improved.

According to one exemplary embodiment of the present disclosure, it is possible to provide a technique for improving the measurement accuracy of the sensor provided in the transport arm.

The embodiments of the present disclosure further include the following aspects.

### (Addendum 1)

A substrate processing system including:
a substrate processing apparatus;
a transport apparatus; and
a controller, in which
the substrate processing apparatus includes
   a substrate processing chamber,
   a substrate support disposed in the substrate processing chamber and having a substrate support surface and a ring support surface, and
   an edge ring disposed on the ring support surface to surround a substrate on the substrate support surface and having a first horizontal surface and a first inclined surface,
the transport apparatus includes
   a transport chamber,
   a transport arm configured to transport the substrate between the transport chamber and the substrate processing chamber,
   an optical sensor attached to the transport arm,
   a lens structure disposed below the optical sensor and having a second horizontal surface and a second inclined surface, and
   an actuator attached to the transport arm and configured to move the lens structure in a horizontal direction between a first horizontal position and a second horizontal position, in which the first horizontal position is a position at which the second horizontal surface overlaps an optical axis of the optical sensor and the second horizontal position is a position at which the second inclined surface overlaps the optical axis of the optical sensor, and
the controller is configured to determine a consumption amount of the first horizontal surface based on an output of the optical sensor when the lens structure is at the first horizontal position, and determine a consumption amount of the first inclined surface based on an output of the optical sensor when the lens structure is at the second horizontal position.

### (Addendum 2)

The substrate processing system according to Addendum 1, in which
the optical sensor is configured to measure a first distance from the optical sensor to the first horizontal surface via the second horizontal surface when the lens structure is at the first horizontal position, and
the controller is configured to determine the consumption amount of the first horizontal surface based on the first distance.

### (Addendum 3)

The substrate processing system according to Addendum 2, in which
the optical sensor is configured to measure a second distance from the optical sensor to the first inclined surface via the second inclined surface when the lens structure is at the second horizontal position, and
the controller is configured to determine the consumption amount of the first inclined surface based on the second distance.

### (Addendum 4)

The substrate processing system according to Addendum 1, in which
the optical sensor is configured to measure a distance from the optical sensor to the first inclined surface via the second inclined surface when the lens structure is at the second horizontal position, and
the controller is configured to determine the consumption amount of the first inclined surface based on the distance.

### (Addendum 5)

The substrate processing system according to any one of Addenda 1 to 4, in which the actuator is a piezo actuator.

### (Addendum 6)

A substrate processing system including:
a substrate processing apparatus;
a transport apparatus; and
a controller, in which
the substrate processing apparatus includes
   a substrate processing chamber, and
   a consumable component constituting a part of the substrate processing chamber or disposed in the substrate processing chamber, and having a first horizontal surface and a first inclined surface,
the transport apparatus includes
   a transport chamber,
   a transport arm configured to transport a substrate between the transport chamber and the substrate processing chamber,
   an optical sensor attached to the transport arm,
   a lens structure disposed above or below the optical sensor and having a second horizontal surface and a second inclined surface, and
   an actuator attached to the transport arm and configured to move the lens structure in a horizontal direction between a first horizontal position and a second horizontal position, in which the first horizontal position is a position at which the second horizontal surface overlaps an optical axis of the optical sensor and the second horizontal position is a position at which the second inclined surface overlaps the optical axis of the optical sensor, and
the controller is configured to determine a state of the consumable component based on an output of the optical sensor.

### (Addendum 7)

The substrate processing system according to Addendum 6, in which
the optical sensor is configured to measure a first distance from the optical sensor to the first horizontal surface via the second horizontal surface when the lens structure is at the first horizontal position, and
the controller is configured to determine a consumption amount of the first horizontal surface based on the first distance.

### (Addendum 8)

The substrate processing system according to Addendum 7, in which
the optical sensor is configured to measure a second distance from the optical sensor to the first inclined surface via the second inclined surface when the lens structure is at the second horizontal position, and
the controller is configured to determine a consumption amount of the first inclined surface based on the second distance.

### (Addendum 9)

The substrate processing system according to Addendum 6, in which
the optical sensor is configured to measure a distance from the optical sensor to the first inclined surface via the second inclined surface when the lens structure is at the second horizontal position, and
the controller is configured to determine a consumption amount of the first inclined surface based on the distance.

### (Addendum 10)

The substrate processing system according to Addendum 6, in which
the optical sensor is configured to measure a first distance from the optical sensor to the first horizontal surface via the second horizontal surface when the lens structure is at the first horizontal position, and
the controller is configured to determine a position of the consumable component with respect to a reference position based on the first distance.

### (Addendum 11)

The substrate processing system according to Addendum 10, in which
the optical sensor is configured to measure a second distance from the optical sensor to the first inclined surface via the second inclined surface when the lens structure is at the second horizontal position, and
the controller is configured to determine the position of the consumable component with respect to the reference position based on the first distance and the second distance.

### (Addendum 12)

The substrate processing system according to Addendum 6, in which
the optical sensor is configured to measure a distance from the optical sensor to the first inclined surface via the second inclined surface when the lens structure is at the second horizontal position, and
the controller is configured to determine a position of the consumable component with respect to a reference position based on the distance.

### (Addendum 13)

The substrate processing system according to any one of Addenda 6 to 12, in which the actuator is a piezo actuator.

### (Addendum 14)

A substrate processing system including:
a substrate processing apparatus;
a transport apparatus; and
a controller, in which
the substrate processing apparatus includes
   a substrate processing chamber, and
   a consumable component constituting a part of the substrate processing chamber or disposed in the substrate processing chamber, and having a first inclined surface,
the transport apparatus includes
   a transport chamber,
   a transport arm configured to transport a substrate between the transport chamber and the substrate processing chamber,
   a sensor attached to the transport arm, and
   a lens structure having a second inclined surface disposed above or below the sensor, and,
the controller is configured to determine a state of the consumable component based on an output of the sensor.

Each of the above embodiments is described for the purpose of description, and it is not intended to limit the scope of the present disclosure. Each of the above embodiments may be modified in various ways without departing from the scope and gist of the present disclosure. For example, some configuration elements in one embodiment are able to be added to another embodiment. In addition, some configuration elements in one embodiment are able to be replaced with corresponding configuration elements in another embodiment.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

What is claimed is:

1. A substrate processing system comprising:
a substrate processing apparatus;
a transport apparatus; and
controller circuitry, wherein
the substrate processing apparatus includes
a substrate processing chamber,
a substrate support disposed in the substrate processing chamber and having a substrate support surface and a ring support surface, and
an edge ring disposed on the ring support surface to surround a substrate on the substrate support surface and having a first horizontal surface and a first inclined surface,
the transport apparatus includes
a transport chamber,
a transport arm to transport the substrate between the transport chamber and the substrate processing chamber,
an optical sensor attached to the transport arm,
a lens structure disposed below the optical sensor and having a second horizontal surface and a second inclined surface, and
an actuator attached to the transport arm and to move the lens structure in a horizontal direction between a first horizontal position and a second horizontal position, in which the first horizontal position is a position at which the second horizontal surface overlaps an optical axis of the optical sensor and the second horizontal position is a position at which the second inclined surface overlaps the optical axis of the optical sensor, and
the controller circuitry is configured to determine a consumption amount of the first horizontal surface based on an output of the optical sensor when the lens structure is at the first horizontal position, and determine a consumption amount of the first inclined surface based on an output of the optical sensor when the lens structure is at the second horizontal position.

2. The substrate processing system according to claim 1, wherein
the optical sensor is configured to measure a first distance from the optical sensor to the first horizontal surface via the second horizontal surface when the lens structure is at the first horizontal position, and
the controller circuitry is configured to determine the consumption amount of the first horizontal surface based on the first distance.

3. The substrate processing system according to claim 2, wherein
the optical sensor is configured to measure a second distance from the optical sensor to the first inclined surface via the second inclined surface when the lens structure is at the second horizontal position, and
the controller circuitry is configured to determine the consumption amount of the first inclined surface based on the second distance.

4. The substrate processing system according to claim 1, wherein
the optical sensor is configured to measure a distance from the optical sensor to the first inclined surface via the second inclined surface when the lens structure is at the second horizontal position, and
the controller circuitry is configured to determine the consumption amount of the first inclined surface based on the distance.

5. The substrate processing system according to claim 1, wherein the actuator is a piezo actuator.

6. A substrate processing system comprising:
a substrate processing apparatus;
a transport apparatus; and
controller circuitry, wherein
the substrate processing apparatus includes
a substrate processing chamber, and
a consumable component constituting a part of the substrate processing chamber or disposed in the substrate processing chamber, and having a first horizontal surface and a first inclined surface,
the transport apparatus includes
a transport chamber,
a transport arm to transport a substrate between the transport chamber and the substrate processing chamber,
an optical sensor attached to the transport arm,
a lens structure disposed above or below the optical sensor and having a second horizontal surface and a second inclined surface, and
an actuator attached to the transport arm and to move the lens structure in a horizontal direction between a first horizontal position and a second horizontal position, in which the first horizontal position is a position at which the second horizontal surface overlaps an optical axis of the optical sensor and the second horizontal position is a position at which the second inclined surface overlaps the optical axis of the optical sensor, and
the controller circuitry is configured to determine a state of the consumable component based on an output of the optical sensor.

7. The substrate processing system according to claim 6, wherein
the optical sensor is configured to measure a first distance from the optical sensor to the first horizontal surface via the second horizontal surface when the lens structure is at the first horizontal position, and
the controller circuitry is configured to determine a consumption amount of the first horizontal surface based on the first distance.

8. The substrate processing system according to claim 7, wherein
the optical sensor is configured to measure a second distance from the optical sensor to the first inclined surface via the second inclined surface when the lens structure is at the second horizontal position, and
the controller circuitry is configured to determine a consumption amount of the first inclined surface based on the second distance.

9. The substrate processing system according to claim 6, wherein
the optical sensor is configured to measure a distance from the optical sensor to the first inclined surface via the second inclined surface when the lens structure is at the second horizontal position, and
the controller circuitry is configured to determine a consumption amount of the first inclined surface based on the distance.

10. The substrate processing system according to claim 6, wherein
the optical sensor is configured to measure a first distance from the optical sensor to the first horizontal surface via the second horizontal surface when the lens structure is at the first horizontal position, and
the controller circuitry is configured to determine a position of the consumable component with respect to a reference position based on the first distance.

11. The substrate processing system according to claim 10, wherein
the optical sensor is configured to measure a second distance from the optical sensor to the first inclined surface via the second inclined surface when the lens structure is at the second horizontal position, and
the controller circuitry is configured to determine the position of the consumable component with respect to the reference position based on the first distance and the second distance.

12. The substrate processing system according to claim 6, wherein
the optical sensor is configured to measure a distance from the optical sensor to the first inclined surface via the second inclined surface when the lens structure is at the second horizontal position, and
the controller circuitry is configured to determine a position of the consumable component with respect to a reference position based on the distance.

13. The substrate processing system according to claim 6, wherein the actuator is a piezo actuator.

14. A substrate processing system comprising:
a substrate processing apparatus;
a transport apparatus; and
controller circuitry, wherein
the substrate processing apparatus includes
a substrate processing chamber, and
a consumable component constituting a part of the substrate processing chamber or disposed in the substrate processing chamber, and having a first inclined surface,
the transport apparatus includes
a transport chamber,
a transport arm to transport a substrate between the transport chamber and the substrate processing chamber,
a sensor attached to the transport arm, and
a lens structure having a second inclined surface disposed above or below the sensor, and,
the controller circuitry is configured to determine a state of the consumable component based on an output of the sensor.

15. The substrate processing system according to claim 1, wherein
the optical sensor is configured to measure a first distance from the optical sensor to the first horizontal surface via the second horizontal surface when the lens structure is at the first horizontal position.

16. The substrate processing system according to claim 2, wherein
the optical sensor is configured to measure a second distance from the optical sensor to the first inclined surface via the second inclined surface when the lens structure is at the second horizontal position.

17. The substrate processing system according to claim 1, wherein
the optical sensor is configured to measure a distance from the optical sensor to the first inclined surface via the second inclined surface when the lens structure is at the second horizontal position.

18. The substrate processing system according to claim 6, wherein
the optical sensor is configured to measure a first distance from the optical sensor to the first horizontal surface via the second horizontal surface when the lens structure is at the first horizontal position.

19. The substrate processing system according to claim 7, wherein
the optical sensor is configured to measure a second distance from the optical sensor to the first inclined surface via the second inclined surface when the lens structure is at the second horizontal position.

20. The substrate processing system according to claim 6, wherein
the optical sensor is configured to measure a distance from the optical sensor to the first inclined surface via the second inclined surface when the lens structure is at the second horizontal position.
